(19) United States
(12) Patent Application Publication
(10) Pub. No.: US 2025/0277122 A1
(43) Pub. Date: Sep. 4, 2025

(54) Photopolymerizable HOE Composition

(71) Applicant: Xetos AG, Hohenbrunn (DE)

(72) Inventor: Frank Knocke, Ebersberg (DE)

(21) Appl. No.: 18/276,767

(22) PCT Filed: Feb. 11, 2022
(86) PCT No.: PCT/EP2022/053415

§ 371 Date: Aug. 10, 2023

(30) Foreign Application Priority Data
Feb. 11, 2021 (EP) 21156669.0

(51) Int. Cl. C09D 11/101; C09D 11/107; G03H 1/02

(52) U.S. Cl. CPC C09D 11/101; C09D 11/107; G03H 1/02; G03H 2001/0264; G03H 2260/12

(57) ABSTRACT

The present invention relates to photopolymerizable compositions and elements made therefrom, as well as their use. The photopolymerizable compositions are particularly suitable as recording material for optical elements with refractive index modulation, in particular holograms.

### CROSS-REFERENCE TO RELATED APPLICATIONS

This application is the United States national phase of International Application No. PCT/EP2022/053415 filed Feb. 11, 2022, and claims priority to European Patent Application No. 21156669.0 filed Feb. 11, 2021, the disclosures of which are hereby incorporated by reference in their entireties.

### BACKGROUND OF THE INVENTION

### Field of the Invention

The present invention relates to photopolymerizable compositions and elements made therefrom, as well as their use. The photopolymerizable compositions are particularly suitable as recording material for optical elements with refractive index modulation, in particular holograms.

### Description of Related Art

A variety of holograms such as reflection holograms, embossing holograms or transmission holograms or volume holograms are known.

A volume hologram is produced, for example, by interfering two light waves of the same wavelength, also called object and reference beam, and exposing a holographic recording medium, usually photographic film, with the resulting interference pattern, which is usually an intensity pattern. The holographic exposure process and the duplication of the hologram (replication) are technically complex optical processes that require special application knowledge. Methods for creating holograms and the theory are described extensively in the literature [Howard M. Smith, “Principles of Holography”, Wiley (1969)] [Fred Unterseher, et al. “Holography Handbook: Making Holograms the Easy Way”, Ross Books (1982)] [Graham Saxby, “Practical Holography”, Inst, of Physics Pub. (2004)]. Known recording materials with different property profiles and applications are: Silver halide emulsions, cured dichromate gelatin, ferroelectric crystals, photochromic and dichroid materials, and photopolymers [Howard M. Smith, “Principles of Holography”, Wiley (1969).]. For high volume applications, materials of interest are those that can be easily integrated into hologram production and duplication equipment and that allow for easy holographic exposure and development. Photopolymers are considered particularly preferred due to their high efficiency, ease of handling and good storage stability. The best known photopolymers are from DuPont, e.g. Omnidex HRF 600 [S. M. Schultz, et al. “Volume grating preferential-order focusing waveguide coupler,” Opt. Lett, vol. 24, pp. 1708-1710, December 1999]. Omnidex materials belong to the class of self-developing photopolymer films based on radical polymerization and monomer diffusion (see EP 0 324 480 A2).

Omnidex photopolymers have been further developed over the years, primarily with the aim of increasing the refractive index contrast and achieving a high diffraction efficiency in the film (see U.S. Pat. No. 4,942,112 A and DE 69032682 T2). Nevertheless, the application-relevant diffraction efficiencies of well over ⅔ are bought by a high proportion of thermoplastic binder.

In film production, the binder for the coating must be liquid. For this purpose, a solvent is used, the evaporation of which leads to a strong decrease in the layer thickness after coating. The wet layer to be applied is therefore much thicker than the resulting film layer, depending on the solvent content. The solvent content is usually about 80%. In order to achieve a layer of 20 μm that can be exposed by volume holography, a wet layer of 100 μm must be applied in this case. The required high thickness of the wet layer prevents or complicates the use of known printing processes, such as flexographic or gravure printing. In screen printing, the use of fast-drying solvents can cause the mesh to stick together.

Moreover, the film can only be further processed or wound up when all the solvent has evaporated. In production, therefore, a long drying line must be set up with a health- and environment-friendly extraction system, as well as a dust- and explosion-proof environment. This effort means that film production and holographic exposure usually take place at separate locations and times.

In the case of binder-containing materials, thermal post-treatment (“annealing”) of the exposed and UV-fixed photopolymer is also necessary to achieve the maximum refractive index contrast (see DE 68905610 T2). Annealing is an additional time-consuming processing step that slows down, complicates and increases the cost of hologram production in addition to the time-consuming film production, and also limits the choice of substrate materials to those that are not temperature-sensitive.

Other photopolymer materials for volume holography have been developed by Polaroid (see U.S. Pat. No. 5,759,721 A), Fuji Photo Film (see EP 1510862 A2), Konica Minolta Medical & Graphic (see US200505891 A1), Dai Nippon Printing (see EP 123151 A1), Nippon Paint (see EP 21 1615 A2), Nissan Chemical Industries (see US20050068594 A1), Bayer (see WO 2010091795 A1), Xetos (see WO 2003036389 A1) and InPhase Technologies (see US2002142227 A1). The prior art features photopolymers that differ from Omnidex in their holographic properties or processing. Technical progress is documented by reduced oxygen sensitivity, reduced material shrinkage during exposure, adjusted spectral sensitivity, solvent-free film production, higher diffraction efficiency without annealing and/or better temperature and storage stability.

A newer and commercially available holographic photopolymer is the “Bayfol HX” film developed by Bayer Materialscience. This does not contain a thermoplastic binder but a polyurethane as the polymer matrix that holds the holographically exposable writing monomers. The polyurethane is formed by polyaddition from a polyisocyanate and polyol mixture. The reactive components are mixed together just before coating and cure on the carrier film. Although there is no high solvent content as with the previously described binder-containing materials, the curing time of up to one hour poses the same problem of providing a sufficiently long dust-free drying or curing section in the coating system.

As with all commercially available photopolymer films, the user cannot freely choose the carrier material and coat it himself, but must process the film structure supplied. In addition to the carrier film, there is also a laminating film on the light-sensitive film layer to prevent adhesion and contamination. Peeling off this film can cause a static charge that attracts dust particles. Since the film must be laminated to either glass or a master for exposure, where every particle of dust creates a flaw, an extremely dust-free environment is required for clean and flawless processing.

Photopolymer systems containing a polymeric binder or polymeric matrix form an essentially solid film layer. In contrast, binder-free systems that are essentially liquid until exposure have also been presented (see, for example, U.S. Pat. No. 3,993,485 A or N. Smirnova, Optics in Information Systems, February 2004, p. 9 or Xetos (see WO 2003036389 A1).

In most essentially solid monomer-binder/matrix photopolymers, unexposed writing monomers located in the area of the dark interference lines diffuse into the exposed polymerized areas after holographic laser exposure. This creates a refractive index difference whose spatial modulation corresponds to the interference pattern to be recorded. However, the diffusion of the writing monomers in the solid matrix takes time. An increase in temperature can accelerate this process. DuPont specifies an annealing time of one hour at 120° C. for the OmniDex® material mentioned. In the case of the Bayfol HX material, the patent applications (EP 2 372 454 A1 p. 13 [0127], EP 2 219 073 A1 p. 15 [0102]) specify a waiting time of 5 min before the material is finally completely cured with UV light.

For many production processes, however, the shortest possible times or the highest possible throughput and simple, cost-effective process control are required for the production of the holograms, so that cumbersome and time-consuming post-treatments or waiting times are a disadvantage.

For this reason, photopolymerizable compositions were developed that form an effective refractive index modulation already during laser exposure and can be immediately fixed with UV light, as described in EP 1 779 196 B1. Various triglycerides, such as castor oil, were used there.

The castor oil is an inert component that does not cross-link during exposure. This means that it can migrate out of the layer later. To reliably prevent this, the hologram layer is usually subsequently sealed with a UV varnish layer.

However, if the castor oil content is too high, this can happen during or shortly after exposure. Too high a proportion also leads to turbidity. The higher the castor oil content, the higher the exposure temperature must be to ensure a clear layer. However, increasing the temperature reduces the viscosity of the photopolymerizable composition, which has a negative effect on holographic exposability. There is therefore an upper limit of the castor content and the exposure temperature, which must not be exceeded for holographic exposure.

Besides the disadvantage that the exposed layer must be sealed relatively quickly with a UV varnish to prevent the castor oil from oozing out, these photopolymerizable compositions have a relatively high turbidity. The thicker the layers and the higher the triglyceride content, the more noticeable the material haze.

For security elements and labels that are applied to a non-transparent substrate, this is not so noticeable. But especially for holographic optical elements (HOE's) an unobstructed view is desirable and often necessary, e.g. if the holograms are to be used in head-up displays or in augmented/mixed reality glasses. In contrast to holographic security elements, where very thin layers of less than 20 μm are desired, the layer thicknesses for HOEs can be much thicker in the range of more than 100 μm. Thick layers are sometimes even desired to compensate for tolerances of the optical components that are to be combined or bonded with the hologram layer. Thick layers are also often necessary if only a very narrow spectral range of light is to be reflected. However, depending on their viscosity, liquid photopolymerizable compositions only form high refractive index differences up to a certain layer thickness. Above a certain thickness, the dynamics of the liquid and the shrinkage during curing are simply too great to effectively and uniformly record a pattern in the range of the light wavelength. This is especially true with holographic dual beam or master exposures. In contrast, the large-scale production of essentially solid film materials with layer thicknesses greater than 20 μm is very costly and not worthwhile due to the currently still low demand. The Bayfol-HX 200 material from Covestro is offered with a film thickness of 16 μm. The haze value is specified as <2% (Product Information Sheet-Bayfol HX 200, Edition 2018 Mar. 1).

In addition to the lowest possible haze value, a holographic element that is integrated into the windscreen of a car for a head-up display must also meet other requirements. During production, the laminated glass pane is exposed to temperatures of 140° C. and pressures of 12 bar for up to 90 minutes in an autoclave (WO 03033583 A1). The holographic material and the hologram it contains must also survive this without damage or loss of quality.

The diffraction efficiency (BWG, “Beugungswirkungsgrad”) η of volume holograms depends on their layer thickness d and on Δn. Δn denotes the amplitude of the refractive index modulation within the hologram layer. According to the coupled wave theory of Kogelnik (see; H. Kogelnik, The Bell System Technical Journal, Volume 48, November 1969, Number 9 Page 2909-Page 2947), the higher the Δn-value, the thinner the layers can be to achieve a high BWG-value. For reflection holograms from surface mirrors or Lippmann-Bragg holograms, where the refractive index modulation is parallel to the surface, the following relationship applies

$$η = {tanh}^{2} ( \frac{π \cdot Δ n \cdot d}{λ} ) , \qquad ( F - 1 )$$

where λ is the wavelength of the light. For thick layers, the Δn-value of the holographic recording materials can therefore be lower than for thin layers in order to achieve the same diffraction efficiency.

With the photopolymerizable composition, both transmission and reflection holograms can be recorded. The achievable amplitude of the refractive index modulation Δn for the Lippmann-Bragg holograms with a layer thickness of more than 100 μm, whose grating lines run parallel to the surface, is thereby greater than 0.001, preferably greater than 0.002 and particularly preferably greater than 0.003.

Using the wavelength λ from the absorption peak measured in the spectrometer during perpendicular transillumination, the diffraction efficiency η (BWG) and the layer thickness d, Δn can be calculated for these holograms as follows.

$$Δ n = \frac{λ}{π \cdot d} \cdot arc tanh ( \sqrt{η} ) , \qquad ( F - 2 )$$

### SUMMARY OF THE INVENTION

The present invention is thus based on the object of providing a photopolymerizable composition which avoids the disadvantages of known recording materials and which advantageously enables holographic exposure of thick layers of more than 20 μm, preferably more than 50 μm and particularly preferably more than 100 μm. As with the liquid holographic material known from application EP1779196B1, very fast processing suitable for mass production should be possible. The holographic elements produced from a photopolymerizable composition should also have a high long-term stability as well as a thermal and mechanical stability. Furthermore, an additional sealing should not be absolutely necessary. Particularly preferably, the cured material and the hologram recorded therein should survive the autoclave process for producing a laminated glass pane undamaged. Preferably, the photopolymerizable composition should be applicable to processes in which pressures above 5 bar and temperatures above 100° C., and particularly preferably pressures above 10 bar and temperatures above 120° C., act on the photopolymerizable composition or elements made therefrom.

Surprisingly, it was found that the inert components such as the castor oil in the formulation described in EP 1 779 196 B1 can be advantageously replaced by suitable aliphatic urethane acrylates, which also crosslink on exposure and therefore cannot sweat out.

The object is thus solved according to the invention by a photopolymerizable composition which is curable by UV/VIS irradiation, comprising:
a) 25 to 74.9% by weight of at least one monomer M comprising at least one ethylenically unsaturated group or a monomer mixture comprising at least two monomers M and M1 comprising different ethylenically unsaturated groups,
b) 25 to 74.9% by weight of an aliphatic urethane acrylate or a mixture of different aliphatic urethane acrylates,
c) 0.1 to 10% by weight of a photoinitiator which activates the polymerization of the monomers and urethane acrylates upon exposure to actinic radiation;
   wherein the photopolymerizable composition is liquid at a standard pressure in the range of 15° C. to 150° C.

### BRIEF DESCRIPTION OF THE DRAWINGS

FIG. 1 shows the schematic construction of a compact roll-to-roll machine for the production of holographic contact copies from the photopolymerizable composition of the present invention;

FIG. 2 shows the schematic exposure setup;

FIG. 3 shows the beam path; and

FIG. 4 shows the measurement curve with the corresponding measurement points of sample C.

### DESCRIPTION OF THE INVENTION

Figures in % by weight refer to the total weight of the photopolymerizable composition, unless otherwise stated.

Actinity (actinic radiation) can be understood as the photochemical effectiveness of electromagnetic radiation of different wavelengths.

The term is used, for example, when evaluating the physiological consequences of laser light of different colors or the spectral sensitivity of photographic films and papers. In photochemistry, actinic chemicals are those that are sensitive to light or radiation.

Preferably, component a) contains a bisphenol A diacrylate in an amount within this component of more than 25% by weight, preferably of more than 50% by weight and particularly preferably of more than 90% by weight, based on the total weight of component a).

Particularly preferred as component b) is an aliphatic urethanediacrylate resin, especially Ebecryl 230 from Allnex, or a difunctional aliphatic urethanediacrylate resin, especially CN9002 from Sartomer.

Preferably, the aliphatic urethane acrylate or urethane acrylate mixture has a much slower cross-linking rate than the monomer or monomer mixture. During holographic exposure, the slow reacting component is displaced from the light areas of the interference pattern. This segregation causes the urethane acrylate content to be higher in the dark areas of the interference pattern than in the light areas. Since the urethane acrylate or urethane acrylate mixture has a different refractive index than the monomer or monomer mixture, the refractive index in the layer is modulated according to the interference pattern and a hologram is created. The difference between the refractive indices of the two components at 20° C. should be at least 0.02, preferably at least 0.05 and more preferably at least 0.07. Preferably, the difference between the refractive indices of component a) and component b) at 20° C. is at least 0.02.

The refractive index can be measured with a refractometer, e.g. an analogue Abbe refractometer.

The Abbe refractometer is an optical device for determining the refractive index n of liquids. The measuring principle is based on the determination of the critical angle for total reflection. For this purpose, the liquid is enclosed between two glass prisms and transilluminated as standard at a temperature of 20° C. with light of a wavelength of 589 nm (sodium D-line). After setting the critical angle, the refractive index can be read on a scale.

Preferably, the urethane acrylates may be reaction products of (meth)acrylic acids, polyols and polyfunctional isocyanates. Urethane acrylates are produced, for example, from alcohols containing (meth)acrylolyl groups and di- or polyisocyanates. Manufacturing processes for urethane acrylates are known in principle and described, for example, in DE-A-1 644 798, DE-A 2 115 373 or DE-A-2 737 406. Alcohols containing (meth)acrylolyl groups are esters of acrylic acid or methacrylic acid with a free hydroxyl group and diva-lent alcohols such as 2-hydroxyethyl, 2- or 3-hydroxypropyl or 2-, 3-, 4-, hydroxybutyl (meth)acrylate as well as any mixtures of such compounds. In addition, monovalent alcohols containing (meth)acryloyl groups or reaction products consisting essentially of such alcohols, which are obtained by esterification of n-valent alcohols with (meth)acrylic acid, which are obtained by esterification of n-valent alcohols with (meth)acrylic acid and optionally other dicarboxylic acids, are also possible, it also being possible to use mixtures of different alcohols as alcohols, so that n is a whole number or a number which is fractional on a statistical average and is greater than 2 to 4, preferably 3, and in particular preferably n−1 mol of (meth)acrylic acid being used per mol of the alcohols mentioned.

Surprisingly, it was found that the clarity of the exposed layer depends on the exposure time and intensity with which it is exposed or cured. If the layer is exposed quickly for less than 1 s with sufficient intensity, the layer is less turbid than if it is exposed for several seconds with weaker powers. The turbidity (haze) can be measured and is expressed as a haze value in percent. The difference between the fast and slow exposed areas should reach at least 50%, preferably at least 60% and especially preferably at least 70% at an exposure temperature of 21° C. and a film thickness of 1 mm, measured according to the ASTM D 1003 standard procedure. Temperature also has an effect on turbidity. The lower the temperature, the more milky the result. Exposure of different areas at different temperatures can thus also make a difference or further enhance the intensity-dependent effect.

The sensitivity of the photopolymerizable composition should be better than 150 mJ/cm², preferably better than 100 mJ/cm² and particularly preferably better than 50 mJ/cm².

The sensitivity indicates the minimum exposure dose required to create a hologram. The laser must have the right wavelength for the dyes used in the initiator system. For example, when using a red laser with a wavelength of 633 nm, methylene blue is used, and for a green laser with 532 nm, safranin-O is used. The laser wavelength should be close to the spectral absorption maximum of the corresponding dye. The sensitivity can be determined by comparing the exposed holograms. As soon as the measured diffraction efficiency can no longer be improved by increasing the exposure dose for the same layer thickness, the required minimum dose has been reached or exceeded.

Preferably, the composition according to the invention does not require time for evaporation of volatile solvents, chemical reactions or thermal treatments after application to a substrate or copy master. Exposure can take place immediately after application of the composition to a substrate or copy master. Wet application of the composition to the substrate can be done by squeegee, doctor blade or slot dye coating. For thin layers smaller than 20 μm, known printing processes such as screen, gravure, engraving, pad or flexographic printing can also be used. Preferably, the photopolymerizable composition is laminated directly onto the master to be copied using a transparent and clear film. The layer thickness is adjusted either by the contact pressure and the lamination speed or by the slit width. When coating thick and rigid substrates such as glass plates, a spin coating process can be used. Application with an inkjet printing process or with a CNC-controlled dispensing device is also possible. Direct injection into cavities is also possible.

In particular, the photopolymerizable composition is also suitable for application to curved surfaces. It can also be pressed between two matching bodies and used simultaneously as a kit or adhesive.

The user is also free to choose which carrier materials and layer structures to use, since the coating is carried out in the exposure unit. The photopolymerizable composition, which is essentially free of volatile organic solvents and preferably contains less than 5% by weight thereof, more preferably at most 1% by weight, can be exposed immediately after application. Multi-layer exposures are also not a problem, as a new layer can be applied and holographically exposed after curing according to the same principles. This can be used, for example, to build up true-color holograms from three layers for the primary colors red, green and blue.

Aliphatic urethane acrylates with a relatively slow reaction rate and high flexibility are preferred. The flexibility of the cured layer is helpful in removing the exposed hologram from rigid surfaces such as glass or metal. The easy and clean removal is very favourable for mass production because it allows the use of wear-free copy masters such as conventional nickel shims with a fine holographic surface structure or volume holograms sealed with thin glass for making contact copies. Due to the residue-free removal of the non-sticky layer, the cleaning effort remains low.

The photopolymerizable composition is particularly suitable for making contact copies. The fact that the liquid photopolymerizable composition is printed directly onto the master eliminates the need for index matching. This is the application of a liquid between the master and the hologram layer with approximately the same refractive index of the two layers. Index matching prevents the occurrence of disturbing interference phenomena (Newton rings) in the normal contact copying process with film materials. These are caused by reflections that occur especially in places where the two layers do not touch directly, e.g. because of a dust inclusion or a small unevenness, resulting in bubbles or air inclusions. In addition, the compensation of scratches and other unevenness from the substrate and master improves the optical quality of the copy. Small dust particles with a dimension smaller than the layer thickness are embedded in the liquid and do not produce significant print and defect marks as with film materials. This significantly reduces waste and cleanroom demands on the production environment.

Advantageously, the liquid photopolymerizable composition can thus also be used as an index match material for the exposure of holographic film materials. The fact that it hardens during exposure eliminates the need for cleaning or evaporation. In addition, the holographic recording is supported and enhanced by the combination of the two holographic recording materials, as a hologram is created in both layers.

Because the liquid material adapts to any surface, in contrast to film materials, surface structures can be moulded at the same time as the hologram exposure and complex shaped surfaces can be used. The surface structures can be, in particular, embossed holograms or Fresnel structures. This makes it possible to physically and holographically copy both the surface structure and the volume holographic or optical information of the master in a single processing step.

In this way, optical elements such as prisms or lenses with integrated hologram structures can also be produced.

Because the photopolymerizable composition can be exposed immediately after application, compact coating and exposure times with very short transport distances and times between these two stations can be realized. This reduces the risk of unwanted pre-exposure due to ambient light. The requirement for a dark environment is therefore not great. The photopolymerizable composition can be applied and exposed within 1 min, preferably within 20 s, particularly preferably within 5 s.

The invention relates to a process in which the photopolymerizable composition according to the invention is applied and exposed within one minute.

The photopolymerizable composition according to the invention comprises at least one monomer M comprising at least one ethylenically unsaturated group, preferably a monomer M comprising at least two ethylenically unsaturated groups.

Particularly preferably, the photopolymerizable composition comprises at least one monomer M comprising at least one ethylenically unsaturated group and a monomer M1 comprising at least two ethylenically unsaturated groups, wherein M1 preferably differs from M only by the second ethylenically unsaturated group.

The monomer comprising at least one ethylenically unsaturated group may have the following general structural units.

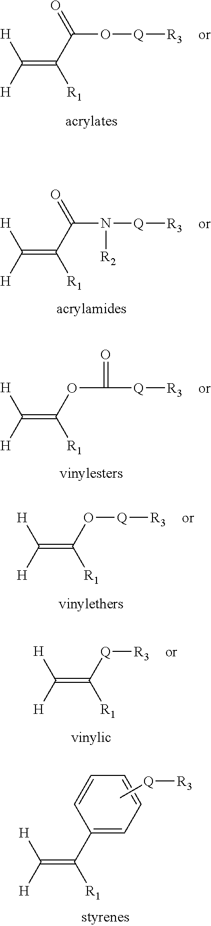

wherein

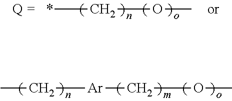

wherein n, m=0-12, preferably 1-12; o=0, 1; and Ar is a mono- or polynuclear substituted or unsubstituted aromatic or heterocyclic aromatic radical,
wherein the radical R₁ is H, methyl or ethyl and
wherein the radicals R₂ and R₃ are independently selected from the group consisting of alkyl, alkenyl, alkynyl, alkoxy, acyl and acyloxy radicals which may be straight or branched chain, unsubstituted or substituted, substituted or unsubstituted aryloxy radicals, substituted or unsubstituted aromatic radicals or heterocyclic radicals, unsubstituted or substituted alicyclic hydrocarbon radicals, aliphatic, aromatic and aliphatic-aromatic amino, carboxylic acid, amido and imido radicals, hydroxy, amino, cyano, nitro, halogen atoms or hydrogen atoms, and combinations of the foregoing radicals, wherein the substituted radicals may be substituted with C₁-C₁₂ alkyl, C₁-C₁₂ alkoxy, hydroxy, carboxy, carbonyl, amino, amido, imido radicals, halogen atoms, aromatic radicals or combinations thereof.

Examples of suitable monomers M are substituted or unsubstituted styrene monomers, acrylic acid, α-alkylacrylic acid, acrylic acid ester, α-alkylacrylic acid ester, the alcohol component of which can be a substituted or unsubstituted aliphatic or aromatic radical with 2-50 carbon atoms, acrylamide, α-alkylacrylamide, wherein alkyl is as defined above, vinyl esters, vinyl alcohol, vinyl ethers and other substituted vinyl monomers substituted with substituted or unsubstituted aliphatic or aromatic radicals having 2-50 carbon atoms.

Preferred examples of suitable monomers M are (meth)acrylic acid butyl ester, (meth)acrylic acid phenyl ester, (meth)acrylic acid benzyl ester, (meth)acrylic acid isobornyl ester, (meth)acrylic acid cyclohexyl ester, (meth)acrylic acid 2-phenoxyethyl ester, (meth)acrylic acid 1H,1H,2H,2H-perfluorooctyl ester, 2,2,2-trifluoroethyl (meth)acrylate, heptafluoropropyl (meth)acrylate, 1,1,1,3,3,3-hexyfluoroisopropyl (meth)acrylate, 2,2,3,3-tetrafluoropropyl (meth)acrylate), 2,2,3,3,4,4,4-heptafluorobutyl (meth)acrylate, 2,2,3,3,4,4,5,5-octafluoropentyl (meth)acrylate, acrylic acid N,N-diethylaminoethyl ester, acrylic acid ethoxyethyoxyethyl ester, acrylic acid 2-(p-chlorophenoxy)ethyl ester, p-chlorophenyl acrylate, 2-phenylethyl (meth)acrylate, pentachlorophenyl acrylate, phenyl acrylate, p-chlorostyrene, n-vinylcarbazole, 1-vinyl-2-pyrolidone, 2-chlorostyrene, 2-bromo-styrene, methoxystyrene, phenol ethoxylate acrylate, 2-(p-chlorophenoxy)ethyl acrylate, 2-(1-naphthyloxy)ethyl acrylate, hydroquinone monomethacrylate and 2-[·-(N-carba-zolyl)propionyloxy]ethyl acrylate.

Particularly preferred monomers M are N-vinyl carbazole, ethoxyethoxyethyl acrylate, 2-naphthyl acrylate, 2-phenoxyethyl acrylate, 2-phenoxyethyl methacrylate, phenol ethoxylate acrylate, 2-(p-chlorophenoxy)ethyl acrylate, p-chlorophenyl acrylate, phenyl acrylate, 2-phenylethyl acrylate, 2-(1-naphthyloxy)ethyl acrylate, t-butyl acrylate, isobornyl acrylate, cyclohexyl acrylate, N,N-diethylaminoethyl acrylate, acrylamide, ethoxyethoxyethyl acrylate, 1H,1H,2H,2H-perfluorooctyl methacrylate and pentafluoroethyl acrylate.

Preferably, the monomer M comprises at least two ethylenically unsaturated groups, hence the monomer is preferably difunctional.

Difunctional ethylenically unsaturated monomers have two C—C double bonds in the molecule, i.e. they contain e.g. two of the structural units indicated above. A difunctional ethylenically unsaturated monomer may contain, for example, two acrylate or methacrylate groups.

The monomer M in the photopolymerizable composition according to the invention may consist exclusively of one or more difunctional or higher functional monomers, i.e. the composition may be free of monofunctional ethylenically unsaturated monomers. Preferably, the content of monomers M having at least two ethylenically unsaturated groups in the composition according to the invention is more than 10% by weight, preferably more than 20% by weight, and particularly preferably more than 30% by weight, based on the total weight of the composition.

The use of difunctional or higher functional monomers leads in particular to a particularly high thermal and mechanical stability of the produced holographic elements and is especially advantageous in the production of refexion holograms.

Preferred monomers M having at least two ethylenically unsaturated groups are ethoxylated bisphenol A diacrylates, in particular compounds of the following formula

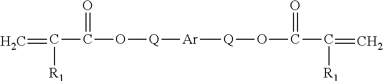

wherein R₁, Q and Ar have the meaning given above.

A particularly preferred monomer M is the compound of the following structural formula:

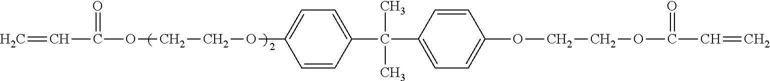

Preferably, the viscosity of the monomer M or monomer mixture is at least 900 mPa·s at room temperature.

The photopolymerizable composition according to the invention comprises an aliphatic urethane acrylate or a mixture of different aliphatic urethane acrylates.

The suitable urethane acrylates are generally compounds of the following general structural formula:

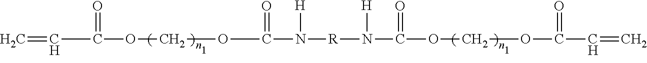

where R is a long polyol segment and NHCOO is the urethane compound. A particularly preferred aliphatic urethane acrylate is the commercially available product Ebecryl 230 from Allnex and CN 9002 from Sartomer; and n₁=0-1000, preferably 0-100, more preferably 1-12.

The urethane acrylate mixture contains 25% of one of these products, preferably more than 50%, or particularly preferably consists of only one of these two products.

The viscosity of the photopolymerizable composition at 20° C. is at least 2000 mPa·s, preferably 10000 mPa·s and particularly preferably at least 20000 mPa·s.

The viscosity can be determined with a plate-plate rotational rheometer (e.g. from Haake, type 006-2805). The material is placed between two coaxial, circular plates, one of which rotates. The plates have e.g. a distance of 1 mm and a diameter of 35 mm. The viscosity can be determined from the measurement of the torque and the speed (e.g. 10 revolutions/s) (DIN53018, ISO3210).

The photopolymerizable composition according to the invention comprises at least one photoinitiator which preferably activates the polymerization of the monomer(s) M and the aliphatic uretane acrylate(s) upon exposure to (actinic) radiation. This is preferably a radical-forming polymerization initiator.

Radical-forming polymerization initiators are known, see e.g. Timpe, H. J. and S. Neuenfeld, “Dyes in photoinitiator systems”, Kontakte (1990), pages 28-35 and Jakubiak, J. and J. F. Rabek, “Photoinitiators for visible light polymisation”, Polimery (Warsaw) (1999), 44, pages 447-461.

Suitable radical-forming polymerization initiators that can be activated by UV radiation and are generally inactive at temperatures up to 185° C. include the substituted or unsubstituted polynuclear quinones; these are compounds with two intracyclic carbon atoms in a conjugated carbocyclic ring system, e.g. 9,10-anthraquinone, 1-chloroanthraquinone, 2-chloroanthraquinone, 2-methylanthraquinone, 2-ethylanthraquinone, 2-tert-butylanthraquinone, octamethylanthraquinone, 1,4-naphthoquinone, 9,10-phenanthrenequinone, 1,2-benzanthraquinone, 2,3-benzanthraquinone, 2-methyl-1,4-naphthoquinone, 2,3-dichloronaphthoquinone, 1,4-dimethylanthraquinone, 2,3-dimethylanthraquinone, 2-phenylanthraquinone, 2,3-diphenylanthraquinone, sodium salt of anthraquinone-α-sulfonic acid, 3-chloro-2-methylanthraquinone, retenquinone, 7,8,9,10-tetrahydronaphthacenequinone and 1,2,3,4-tetrahydrobenz[a]anthracene-7,12-dione. Other photoinitiators that are also useful, although some are thermally active at temperatures as low as 85° C., are described in U.S. Pat. No. 2,760,663, and include vicinal ketaldonyl alcohols such as benzoin, pivaloin, acyloin ethers, e.g. benzoin methyl and ethyl ethers, α-hydrocarbon substituted aromatic acyloins, including α-methylbenzoin, α-allylbenzoin and α-phenylbenzoin.

Photoreducible dyes and reducing agents such as those disclosed in U.S. Pat. Nos. 2,850,445, 2,875,047, 3,097,096, 3,074,974, 3,097,097, 3,145,104 and 3,579,339, can be used as photoinitiators, as well as dyes from the class of phenazines, oxazines and quinones; Michler's ketone, benzophenone, 2,4,5-triphenylimidazolyl dimers with hydrogen donors and mixtures thereof as described in U.S. Pat. Nos. 3,427,161, 3,479,185, 3,549,367, 4,311,783, 4,622,286 and 3,784,557. A useful discussion of dye sensitised photopolymerization can be found in “Dye Sensitized Photopolymerization” by D. F: Eaton in Adv. in Photo-chemistry, vol. 13, D. H. Volman, G. S. Hammond and K. Gollnick, eds, Wiley-Interscience, New York, 1986, pp. 427-487. Similarly, the cyclohexadienone compounds of U.S. Pat. No. 4,341,860 are useful as initiators. Suitable photoinitiators include CDM-HABI, i.e., 2-(o-chlorophenyl)-4,5-bis(m-methoxyphenyl)-imidazole dimer; o-CI-HABI, i.e., 2,2′-bis(o-chlorophenyl)-4,4′,5,5′-tetraphenyl-1,1′-biimidazole; and TCTM-HABI, i.e., 2,5-bis(o-chlorophenyl)-4-(3,4-dimethoxyphenyl)-1H-imidazole dimer, each typically used with a hydrogen donor, e.g. 2-mercaptobenzoxazole.

Particularly preferred UV photoinitiators are IRGACURE® OXE-01 (1,2-octanedione-1-[4-(phenylthio)-phenyl]-2-(O-benzoyloxime) and IRGACURE® OXE-02 (1-[9-ethyl-6-(2-methylbenzoyl)-9H-carbazol-3-yl]ethanone-O-acetyloxime from BASF AG, as well as OMNIRAD-MBF (methylbenzoyl formate), OMNIRAD-TPO (2,4,6-trimethylbenzoyl-di-phenylphosphine oxide), OMNIRAD-TPO-L (ethyl-(2,4,6-trimethylbenzoyl)-phenylphosphinate), OMNIRAD-1173 (2-hydroxy-2-methyl-1-phenylpropanone), OMNIRAD 1000 (mixture of 2-hydroxy-2-methyl-1-phenylpropanone (80%) and 1-hydroxycyclo-hexyl-phenylketone (20%)), OMNIRAD 184 (1-hydroxycyclohexyl-phenylketone), OMNIRAD 819 (bis(2,4,6-trimethylbenzoyl)phenylphosphine oxide), OMNIRAD 2022 (mixture of 2-hydroxy-2-methyl-1-phenylpropanone, bis(2,4,6-trimethylbenzoyl)phenylphosphine oxide and ethyl(2,4,6-trimethylbenzoyl)phenylphosphinate) and OMNICAT 440 (4,4′-di-methyl-diphenyl-iodonium hexafluorophosphate), which are obtainable from IGM Resins and are preferably present in an amount of 0.1 to 10% by weight.-% are used.

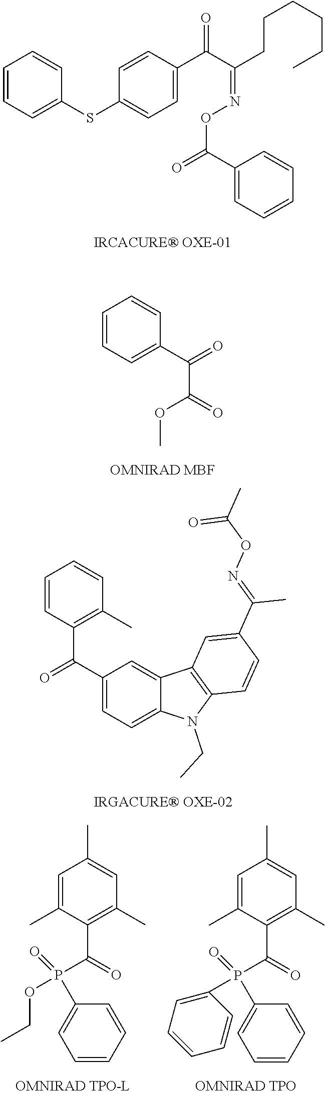

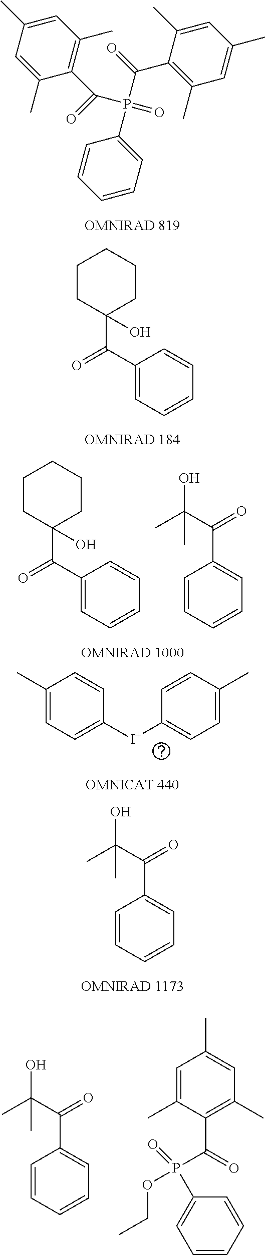

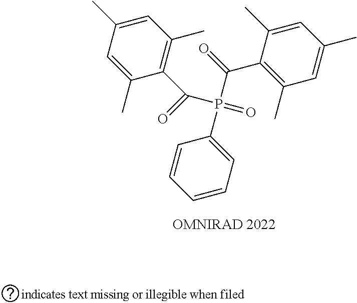

The photoinitiators mentioned above can be used alone or in combination.

Preferably, the photoinitiator comprises a dye and, as co-initiator or co-photoinitiator, a borate salt. The terms “co-initiator” and “co-photoinitiator” are used interchangeably in the context of the present invention.

A particularly preferred photoinitiator comprises the compound of the following structural formula I (co-photoinitiator) and dyes (sensitizers) such as. methylene blue, and the sensitizers disclosed in U.S. Pat. Nos. 3,554,753 A, 3,563,750 A, 3,563,751 A, 3,647,467 A, 3,652,275 A, 4,162,162 A, 4,268,667 A, 4,454,218 A, 4,535,052 A and 4,565,769 A, as well as the dyes and co-photoinitiators referred to in application WO 2012062655 A2, which are expressly referred to herein. Particularly preferred sensitising agents include the following: DBC, i.e., 2,5-bis [(4-diethylamino-2-methylphenyl)methylene]cyclopentanone; DEAW, i.e., 2,5-bis [(4-diethylaminophenyl)methylene]cyclopentanone; dimethoxy-JDI, i.e., 2,3-dihydro-5,6-dimethoxy-2-[(2,3,6,7-tetrahydro-1H,5H-benzo[i,j]quinolizin-9-yl)methylene]-1H-inden-1-one; and safranin O, i.e., 3,7-diamino-2,8-dimethyl-5-phenyl-phenazinium chloride.

The compound with structural formula I, which was developed under the name “CGI 7460” by Ciba Specialty Chemicals Inc. and is now available from BASF AG under the name SEC LCA 1460, is presented as follows:

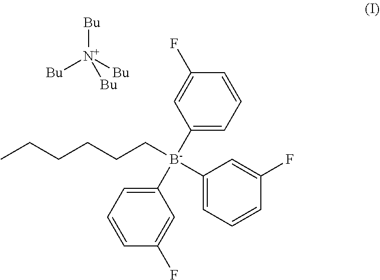

Particularly preferably, the dyes can be provided as dye concentrates (see Table 2 and 3) in a mixture without volatile solvents. This simplifies the preparation of the photopolymerizable compositions, as boiling out the volatile substances is not necessary and the dosage is also easier and more accurate.

Preferably, the dye in the photopolymerizable compositions according to the invention is selected from the group consisting of acriflavins, diaminoacridins, rhodamine B, safranin-O, diethylsafranin and methylene blue.

Preferably, the co-photoinitiator in the photopolymerizable compositions according to the invention is selected from the group consisting of tetrabutylammonium tetrahexylborate, tetrabutylammonium triphenylhexylborate, tetrabutylammonium tris-(3-fluorophenyl)-hexylborate and tetrabutylammonium tris-(3-chloro-4-methylphenyl)-hexylborate or mixtures thereof.

The photoinitiator system that activates the polymerization of the monomers and urethane acrylates upon exposure to actinic radiation consists of a photoinitiator or a co-photoinitiator and a dye. Preferably, it contains all three components mentioned.

To adapt the photopolymerizable composition to the chosen processing method or field of application and to improve printability, surface adhesion, viscosity, film formation, flexibility, hardness, resistance to cold, heat and weathering, the composition may contain various additives known per se.

Therefore, the photopolymerizable composition optionally comprises an additive.

The additives include solvents, fillers, dyes, plasticisers, surfactants, common components used in photopolymer systems, polymeric binders, wetting agents, levelling agents, defoamers, adhesion promoters, surface additives, nanoscale particles, optical brighteners or mixtures thereof.

These should be easy to mix in and should not worsen the diffraction efficiency. Non-volatile substances can even permanently improve the diffraction efficiency in thin films, in particular by choosing additives that increase the refractive index difference between the ethylenically unsaturated monomer and the other components of the photopolymerizable composition. If the urethane component has a lower refractive index than the ethylenically unsaturated monomer component, the additive(s) should also have as low a refractive index as possible. Therefore, in addition to known polymers with a low refractive index such as polyvinyl acetate, fluorinated or silanised polymers are particularly suitable in this case. In order to achieve good diffusion properties, the molecular weight of the additives considered should not be too high.

The additives mentioned above and detailed below can generally be used in an amount of 0.01 to 20% by weight, preferably 0.01 to 10% by weight, based on the total weight of the composition.

The photopolymerizable composition may contain a plasticiser to enhance the modulation of the refractive index of the imaged composition. Plasticisers may be used in amounts ranging from about 0.01% to about 10% by weight, preferably from 5% to about 10% by weight, based on the total weight of the composition. Suitable plasticizers include triethylene glycol, triethylene glycol diacetate, triethylene glycol dipropionate, triethylene glycol dicaprylate, triethylene glycol dimethyl ether, triethylene glycol bis(2-ethylhexanoate), tetraethylene glycol diheptanoate, polyethylene glycol, polyethylene glycol methyl ether, iso-propyl naphthalene, diisopropyl naphthalene, polypropylene glycol, glyceryl tributyrate, diethyl adipate, diethyl sebacinate, dibutyl suberinate, tributyl phosphate, tris(2-ethylhexyl) phosphate, Brij® 30 [C₁₂H₂₅(OCH₂CH₂)₄OH], Brij® 35 [C₁₂H₂₅(OCH₂CH₂)₂₀OH], and n-butyl acetate.

Particularly preferred plasticisers are polyethylene glycol, triethylene glycol diethyl hexanoate (3G8), triethylene glycol dicaprylate, tetraethylene glycol diheptanoate, diethyl adipate, Brij® 30 and tris(2-ethylhexyl) phosphate.

If desired, other common components used in photopolymer systems may be used with the compositions and elements of the present invention. These components include: Optical brighteners, ultraviolet radiation absorbing material, thermal stabilisers, hydrogen donors, oxygen scavengers and release agents. These additives may also include polymers or copolymers.

Useful optical brighteners include those disclosed in U.S. Pat. No. 3,854,950 A. A preferred optical brightener is 7-(4′-chloro-6′-diethylamino-1′,3′,5′-triazin-4′-yl)amino-3-phenyl-coumarin. Ultraviolet radiation absorbing materials useful in the present invention are also disclosed in U.S. Pat. No. 3,854,950 A.

Useful thermal stabilisers include: Hydroquinone, phenidone, p-methoxyphenol, alkyl- and aryl-substituted hydroquinones and quinones, tert-butylcatechol, pyrogallol, copper resinate, naphthylamines, β-naphthole, copper (I) chloride, 2,6-di-tert-butyl-p-cresol, phe-nothiazine, pyridine, nitrobenzene, dinitrobenzene, p-toluchinone and chloranil. Also useful are the dinitroso-dimers described in U.S. Pat. No. 4,168,982 A. Typically, a thermal polymerization inhibitor is also present to increase stability during storage of the photopolymerizable composition.

Hydrogen donor compounds useful as chain transfer reagents include: 2-mercaptobenzoxazole, 2-mercaptobenzothioazole, etc., as well as various types of compounds such as. (a) ethers, (b) esters, (c) alcohols, (d) compounds containing allylic or benzylic hydrogen such as cumene, (e) acetals, (f) aldehydes, and (g) amides, as disclosed in column 12, lines 18 to 58 in U.S. Pat. No. 3,390,996 A, which is specifically referred to herein.

Compounds that have proven useful as release agents are described in U.S. Pat. No. 4,326,010 A. A preferred release agent is polycaprolactone.

The photopolymerizable composition may also contain one or more polymeric binders selected from the group comprising polymethyl methacrylate and polyethyl methacrylate, polyvinyl esters such as polyvinyl acetate, polyvinyl acetate/acrylate, polyvinyl acetate/methacrylate and partially hydrolysed polyvinyl acetate, ethylene/vinyl acetate copolymers, vinyl chloride/carboxylic acid ester copolymers, vinyl chloride/acrylic acid ester copolymers, polyvinyl butyral and polyvinyl formal, butadiene and isoprene polymers and copolymers and polyethylene oxides of polyglycols having an average molecular weight of about 1,000 to 1,000,000 g/mol, epoxides, such as epoxides containing acrylate or methacrylate residues, polystyrenes, cellulose esters, such as cellulose acetate, cellulose acetate succinate and cellulose acetate butyrate, cellulose ethers, such as methyl cellulose and ethyl cellulose, polycondensates, such as polycarbonates, polyesters, polyamides, such as N-methoxymethyl polyhexamethylene adipamide, polyimides, polyurethanes. The polymeric binders mentioned can be used, for example, in an amount of 0.001 to 10% by weight, based on the total weight of the composition.

The photopolymerizable composition may also contain one or more wetting agents (in particular fluorocarbon polymers, such as Schwego-Fluor 8038™, or fluorosurfactants, such as 3M Fluorad FC-4430™), levelling agents (in particular glycolic acid n-butyl esters or polyether-modified polydimethylsiloxanes, such as ADDID 130™), defoamers (in particular defoamers based on fluorosilicone oil, such as ADDID 763™), adhesion promoters (in particular diamino-trimethoxy-functional silane adhesion promoters, such as ADDID 900™ or glycidyl trimethoxy trifunctional silane coupling agents, such as ADDID 911™ vinyl triethyoxysilane or 3-methacryloxypropyl trimethoxysilane), or surface additives (in particular polyether-modified acryl-functional polydimethyl siloxanes, such as BYK-UV 3500™, polyether-modified polydimethylsiloxanes such as BYK-UV 3510™ or polyether-modified acryl-functional polydimethylsiloxanes such as BYK-UV 3530™). The products mentioned with the trade names “ADDID” and “BYK” are available from Wacker and BYK Chemie, respectively.

The photopolymerizable composition may also contain nanoscale particles such as TiO₂, SiO₂ or Au, which may be coupled to monomers (such materials are available, for example, under the trade name “Nanocryl”).

Preferably, the additive can be an amine synergist. An amine synergist in combination with other photoinitiators can increase the curing speed of UV coatings (see DE60216490T2).

Preferably, the additive can be a peroxide. A thermally activatable peroxide, in combination with other photoinitiators, can improve the curing of UV coatings, especially in shaded areas (see U.S. Pat. No. 5,017,406 A or DE 60030223 T2).

Preferably, the additive can also be a marker selected from fluorescent pigments or lanthanide compounds. For example, europium or terbium trisdipicolinate complexes can be used as lanthanide compounds.

For the purposes of the present invention, a marker is understood to be a forensically detectable substance that can be used to determine the authenticity or origin of a product or its producer or seller. Provided that the layers to be produced are thick enough to embed the corresponding microparticles, small individualised particles, colored micro-plastic also known as taggant, can also be introduced.

Preferably, the photopolymerizable composition is liquid at standard pressure in a range from 20° C. to 150° C., more preferably 25° C. to 120° C.

In a further embodiment, the invention comprises an element comprising a component obtainable by exposing the photopolymerizable composition according to the invention to (actinic) UV/VIS radiation.

Preferably, the element according to the invention comprises a component having transparent and/or translucent regions.

If the photopolymerizable composition is exposed to a light source of at most 50 mW/cm² for a period of at least 1 s to 5 min, preferably from 2 s to 2 min, it can become milky. The result is a frosted screen whose scattering properties can be specifically and locally changed by the chosen exposure method (duration, intensity, temperature, etc.). It also makes a difference whether coherent laser light (speckles) or white or UV light is used for exposure. The speckle size can be used, for example, to selectively adjust the graininess. The achievable resolution is very high. Therefore, components can preferably be provided that comprise transparent and/or translucent areas.

With a mask exposure, any structures, texts and images can thus be created that can be recognised independently of a holographic reproduction via their mattness.

In a further embodiment, the invention relates to the use of the element according to the invention as a film, lens, grating, prism, mirror, beam splitter, diffuser, surface relief, optical switch or sensor.

By exposing with a directed beam and a line pattern, milky lamellae that are vertically or obliquely spaced at regular intervals in the layer can be exposed to create a louvre film. This film is transparent in a direction corresponding to the angle of exposure and milky otherwise. Such a film can be used, for example, as an eye protection film for screens.

The whole thing can also be combined with holographic properties by exposing the areas that have not yet been exposed to light quickly and transparently in a holographic manner.

The resulting film then reacts to a certain angle of illumination, for example. Beam deflection and scattering can be coordinated. The use of several layers that are applied one after the other and exposed differently is also conceivable.

In addition, a surface, e.g. a lens structure, can be moulded at the same time. In this way, it is possible to create structures that, for example, bundle the light from an LED array and reproduce it as a directional light beam and other light from LEDs that are not in the lenticular array as scattered light. This scattering can be amplified by the matte areas outside the lens beam paths. The use of a honeycomb structure with matte walls would be a possible embodiment.

One application would be light sources that imitate the natural sky and emit direct directional white-yellow sunlight as well as blue scattered light. The LED array of this artificial “skylight” could of course still vary the brightness and color locally, as with a screen, so that different lighting moods, times of day, cloudy skies, and passing clouds could be simulated.

The blue light could also be filtered from the directed white light beam by a reflection hologram and directed to the scattering centres or surfaces. All this, impression, light bundling, scattering and hologram can be realized with the photopolymerizable composition in one exposure process or combined by repeated application and exposure in several layers.

Directional and diffused light is also needed in automobiles. Directional light for the head-lights that illuminate the road and diffused light, such as for turn signals, brake lights or rear lights that are to be visible to other road users over a wide angle range. By using the special film described and explained above, a headlamp, for example, could be constructed in such a way that it also fulfils the function of a turn signal over its entire surface. The headlamp would be able to emit the directional headlamp light and, if necessary, yellow light scattered in all directions at the same time.

Particularly preferred is an element according to the invention comprising a hologram obtainable by exposing the photopolymerizable composition according to the invention to modulating radiation carrying holographic information.

The holograms are generally produced by exposing a layer of the photopolymerizable composition, which is applied to a carrier substrate or a copy template, to modulated radiation carrying holographic information. The carrier substrates for the production of the elements according to the invention may be glass, plastic, in particular PET, PP, PMMA, polycarbonate or cellulose di or triacetate, or paper. During exposure, the photopolymerizable composition may be located, for example, between two glass plates.

The invention relates to processes for the preparation of an element according to the invention or the photopolymerizable composition according to the invention, in which the element or the composition is subjected to a temperature of more than 100° C. and a pressure of more than 2 bar.

The invention further relates to a method of forming a light stable hologram in a photopolymerizable layer on a substrate surface or copy master, comprising exposing a layer of a photopolymerizable composition according to the invention to modulated radiation carrying holographic information.

Particularly preferred is an element comprising a hologram, wherein the hologram is treated with a swelling agent. A swelling agent in the sense of the present invention is a substance which causes swelling of the hologram by means of diffusion and, in the case of reflective holograms, a spectral shift of the reflected light to a higher wavelength.

For example, a green reflection hologram can be transformed into a red one.

The same methodology can also be used with the flash light. Applied substances evaporate and penetrate the layer like lightning. Surprisingly, this also works when the photopolymer layer is already sealed by a UV varnish layer.

This can be wonderfully used to subsequently individualize a finished hologram. The swelling agent is applied using a common inkjet printing process, for example. Due to the subsequent strong UV flash, the effective substances evaporate and create a swelling and local color changes in the hologram by penetrating where they have been applied. The introduced information can be, for example, a picture, a number or an inscription. Since these changes cannot be reversed and only affect the hologram, this fast and simple process is a good way to increase the counterfeit protection of ID cards, seals or vignettes. Especially for products that are still individualized at the point of issue and where this must be easy to carry out.

Instead of an inkjet printer and flash, a dye-sublimation printer can also be used, which vaporizes the swelling substances via an appropriate printer ribbon.

With thick layers, a concentration gradient can arise. The penetrated material then swells the upper layer more than the deep layers. This leads to a broadening of the absorption peak in the absorption spectrum. A double peak is also possible if the swelling area ends abruptly and the strength of the swelling does not gradually decrease.

A broadening of the peak means that a larger wavelength range is reflected and also that the reproduction angle for a certain wavelength becomes wider. The possibility to change these important parameters of a hologram afterwards is useful for many technical applications, e.g. for HUDs that should also function under a larger reproduction or viewing angle.

The hologram layer can also be brought into contact with a material that contains the swelling agent. This can be, for example, a PVB film with a high plasticizer content such as triethylene glycol diethyl hexanoate (3G8). Depending on the swelling chemicals used and the layer applied to the hologram that contains and can release this swelling agent, their concentration can change after diffusion in the hologram layer depending on the temperature, since the diffusion equilibrium and the concentration gradient between the two layers is temperature-dependent. With the shift of the absorption peak, the reproduction angle for a certain wavelength also changes, this reversible effect can therefore be used as a sensor or optical switch.

If this effect is not desired, e.g. within a laminated glass pane, a sealant, e.g. a UV varnish, can preferably be applied to the hologram, which serves as a protective and barrier layer against diffusing substances.

Particularly preferred is the use of the element according to the invention for a head-up display, a laminated glass pane, data glasses, a light guidance system, a spectrometer, a detection system, a security element or a label.

### EXAMPLES

List of abbreviations

| | |
|---|---|
| BWG, η | Diffraction efficiency |
| CGI 7460 | Tetrabutylammonium tris(3-flourphenyl)hexylborate, |
| | SEC LCA 1460, BASF |
| CN 9002 | Aliphatic urethane acrylate |
| Ebecryl 230 | Aliphatic urethane diacrylate |
| NPG | N-phenylglycine |
| Omnirad 1173 | 2-Hydroxy-2-methyl-1-phenylpropanones |
| PCL-triol | Poly-(caprolactone)-triol, Mₙ ~300 |
| PolyCLO | Capromer PT-05, Polycaprolactone, Mₙ ~540 |
| Safranin-O | 3,7-Diamino-2,8-dimethyl-5-phenyl-phenazinium |
| | chloride |
| Schwego | ethanolic solution of a polyether-based fluorosurfactant |
| Fluor 8038 | from the company Schwegmann |
| SEC LCA 1460 | Tetrabutylammonium tris(3-flourphenyl)hexylborate, |
| | borate salt, co-initiator |
| SR 349 | Ethoxylated bisphenol A diacrylate |
| T_{Peak} | Peak value, transmission at the wavelength that fulfils |
| | the Bragg condition |
| T_{Ref} | Reference value, transmission without hologram |

In the following, the invention is explained in more detail by means of examples. A composition according to Table 1 is known from the prior art.

TABLE 1
Comparison example VB1

| Quantity | Quantity | | |
|---|---|---|---|
| [g] | [%] | Designation | CAS |
| 91.93 | 91.93% | SR 349 | 64401-02-1 |
| 0.03 | 0.03% | Safranin-O | 477-73-6 |
| 0.34 | 0.34% | CGI 7460 | |
| 3.75 | 3.75% | Castor oil | 8001-79-4 |
| 3.75 | 3.75% | Palm kernel oil | 8023-79-8 |
| 0.2 | 0.20% | Schwego Fluor 8038 | — |
| 100 | 100.00% | | |

The composition is known from EP 1 779 196 B1.

### Examples According to the Invention

TABLE 2
Dye concentrates FK1

| Quantity [g] | Quantity [%] | Designation | CAS |
|---|---|---|---|
| 19.55 | 65.17% | PolyCLO TMP540 | 37625-56-2 |
| 10.00 | 33.33% | Omnirad 1173 | 7473-98-5 |
| 0.15 | 0.50% | NPG | 103-01-5 |
| 0.30 | 1.00% | Methylene blue | 61-73-4 |
| 30.00 | 100.00% | | |

TABLE 3
Dye concentrate FK2

| Quantity [g] | Quantity [%] | Designation | CAS |
|---|---|---|---|
| 12.00 | 40.00% | PCL-triol | 37625-56-2 |
| 12.00 | 40.00% | Omnirad 1173 | 7473-98-5 |
| 5.40 | 18.00% | Benzaldehyde | 100-52-7 |
| 0.60 | 2.00% | Methylene blue | 61-73-4 |
| 30.00 | 100.00% | | |

TABLE 4
Monomer-containing mixture MM1

| Quantity [g] | Quantity [%] | Designation | CAS |
|---|---|---|---|
| 287.5 | 57.16% | SR 349 | 64401-02-1 |
| 212.5 | 42.25% | Ebecryl 230 | |
| 3 | 0.60% | SEC LCA 1460 | |
| 503.00 | 100.00% | | |

TABLE 5
Monomer-containing mixture MM2

| Quantity [g] | Quantity [%] | Designation | CAS |
|---|---|---|---|
| 23 | 57.07% | SR 349 | 64401-02-1 |
| 17 | 42.185% | CN 9002 | |
| 0.3 | 0.74% | SEC LCA 1460 | |
| 40.30 | 100.00% | | |

For the exposures of samples A, B and C, the following photopolymerizable compositions were prepared from the monomer-containing mixtures and dye concentrates listed above. The known formulation from Table 1 without the safranin-O was used as a comparative example. Instead of Safranin-O, the dye concentrate FK2 with methylene blue was added to mixture A.

Samples D, E and F were only cured with UV light. Therefore, only the UV photoinitiator Omnirad 1173 was added instead of the dye concentrate.

TABLE 6
Photopolymerizable composition A

| Quantity | Quantity | | |
|---|---|---|---|
| [g] | [%] | Component | Name |
| 5 | 97.09% | VB1 without | Monomer-containing mixture |
| | | Safranin-O | from the comparative example |
| 0.15 | 2.91% | FK2 | Dye concentrate |
| 5.15 | 100.00% | | |

TABLE 7
Photopolymerizable composition B

| Quantity | Quantity | | |
|---|---|---|---|
| [g] | [%] | Component | Name |
| 5 | 97.09% | MM1 | Monomer-containing mixture |
| 0.15 | 2.91% | FK1 | Dye concentrate |
| 5.15 | 100.00% | | |

TABLE 8
Photopolymerizable composition C

| Quantity | Quantity | | |
|---|---|---|---|
| [g] | [%] | Component | Name |
| 5 | 97.09% | MM2 | Monomer-containing mixture |
| 0.15 | 2.91% | FK2 | Dye concentrate |
| 5.15 | 100.00% | | |

TABLE 9
Photopolymerizable composition D

| Quantity | Quantity | | |
|---|---|---|---|
| [g] | [%] | Component | Name |
| 5 | 97.09% | VB1 without | Monomer-containing mixture |
| | | Safranin-O | from the comparative example |
| 0.1 | 1.96% | Omnirad 1173 | Photoinitiator |
| 5.1 | 100.00% | | |

TABLE 10
Photopolymerizable composition E

| Quantity | Quantity | | |
|---|---|---|---|
| [g] | [%] | Component | Name |
| 5 | 97.09% | MM1 | Monomer-containing mixture |
| 0.1 | 1.96% | Omnirad 1173 | Photoinitiator |
| 5.1 | 100.00% | | |

TABLE 11
Photopolymerizable composition F

| Quantity | Quantity | | |
|---|---|---|---|
| [g] | [%] | Component | Name |
| 5 | 97.09% | MM2 | Monomer-containing mixture |
| 0.1 | 1.96% | Omnirad 1173 | Photoinitiator |
| 5.1 | 100.00% | | |

### Exposures

TABLE 12
Laser exposures

| Material | Peak[nm] | BWG[%] | Thickness[μm] | Δn |
|---|---|---|---|---|
| A | 574 | 80% | 124 | 0.0021 |
| B | 578 | 87% | 138 | 0.0022 |
| C | 578 | 96% | 115 | 0.0037 |

The photopolymerizable compositions A, B and C were exposed to a laser with a wavelength of 577 nm in a temperature range of 20° C. to 21° C. The photopolymerizable compositions were kept in an oven at 80° C. and exposed shortly after application. After laser exposure and UV curing, the diffraction efficiency (BWG) was determined using a spectrometer based on the spectral absorption curve. The layer thickness was measured with a digital micrometer outside micrometer gauge.

To show the exposure-dependent haze effect, samples D, E and F were cured with UV light sources of different strengths. For fast curing, the UV bridge described above was used again. Although a much shorter time is sufficient for curing, the samples were irradiated for 30 s. For the slow exposure, the Hamamatsu UV spot light source LC6 was used. The UV light exits at the end of a flexible light guide with the intensity of 3.5 W/cm². The samples were exposed for 120 s at a distance of 6 cm from the exit aperture. Afterwards, to be on the safe side, they were post-cured for another 30 s under the UV bridge.

TABLE 13
UV exposures

| | Haze | Sample thickness | Haze | Sample thickness | | |
|---|---|---|---|---|---|---|
| | value of | or the slow | value of | of the fast | | |
| | the slow | exposure | the fast | exposure | Haze | Temperature |
| Material | exposure | [μm] | exposure | [μm] | difference | [° C.] |
| D | 82% | 948 | 2% | 936 | 80% | 26 |
| D | 89% | 890 | 70% | 855 | 19% | 21 |
| E | 80% | 935 | 2% | 928 | 78% | 21 |
| F | 80% | 950 | 2% | 889 | 78% | 21 |

The photopolymerizable compositions for the UV exposures were kept at a room temperature of 21° C. For the first exposure only, the reference material D was stored and processed at 26° C. The second exposure at 21° C. with photopolymerizable composition D has a high haze value of 70% despite fast exposure, because at this temperature the liquid formulation is already milky.

### Exposure Structure

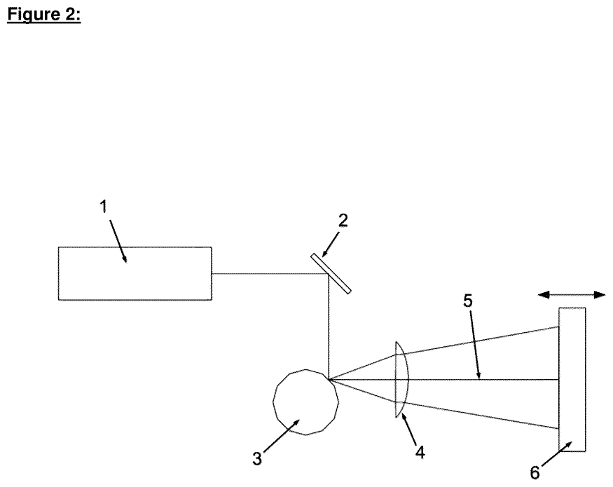

The laser beam with a measured power of 1.43 W was expanded horizontally with a polygon scanner and focused by a cylindrical lens so that it covered an exposure width of 23 cm. FIG. 2 shows the schematic exposure setup.

### REFERENCE SIGNS IN FIG. 2

1 Laser 577 nm
2 Mirror
3 Polygon scanner
4 Cylinder lens
5 Scanning beam
6 Scanner mirror

The respective samples were scanned with this line using a movable mirror and exposed. The traversing speed was set to 9 mm/s. The laser beam fell on the sample surface at an angle of 22° to the perpendicular.

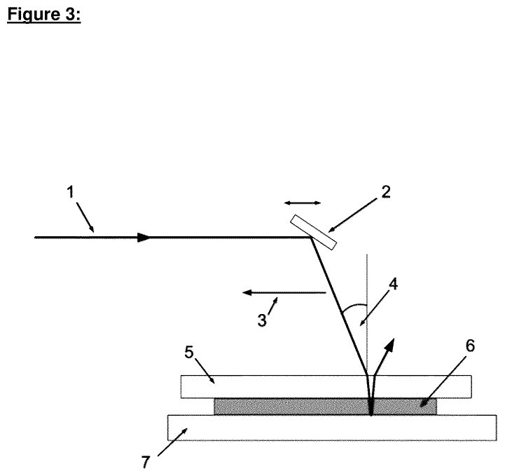

FIG. 3 shows the beam path.

### REFERENCE SIGNS IN FIG. 3

1 Scanning beam 577 nm
2 Scanner mirror
3 Exposure direction
4 Exposure angle, 22°
5 Substrate, glass or foil
6 Photopolymer (photopolymerizable composition)
7 Master, mirror plate

To create a reflection hologram, the sample material was applied to a mirror plate which reflects the laser light back. The interference of the incident beam with the reflected beam creates a line pattern of light and dark spots parallel to the surface of the mirror. This interference pattern is recorded by the material in the form of a refractive index modulation and a so-called Lippmann-Bragg hologram is created.

With laser exposure, the photopolymer layer is between the mirror plate and a transparent substrate, e.g. a PET film or glass. Object glass substrates were used for the examples. The glass is used to cover a drop applied to the mirror plate. The layer thickness results from the drop quantity and the drop expansion. The size of the circular expansion can be controlled by the contact pressure, the temperature and the flow time. Spacers can also be used to achieve a certain layer thickness. After laser exposure, the material is cured with UV light. For the first curing step we use a UV flash with a power of 3000 WS. This is sufficient to remove the hologram with the carrier from the plate. To ensure adhesion to the glass, it should be pre-treated with a primer.

For the final curing of the sample we use a UV bridge with an arc length of 70 mm and a power of 120 W/cm and an exposure time of 30 s.

### Measurement Setup

The samples were measured with a spectrometer (CAS 140 B from Instrument Systems) in transmitted light. This was done with perpendicular illumination. Since the hologram only reflects the wavelength that fulfils the Bragg condition, a clear absorption peak can be seen in the spectral curve at this point.

From the peak value T_{Peak} and a nearby reference value T_{Ref} on the upper baseline, the diffraction efficiency (BWG) n is calculated as follows:

$$η = ( {T}_{Ref} - {T}_{Peak} ) / {T}_{Ref}$$

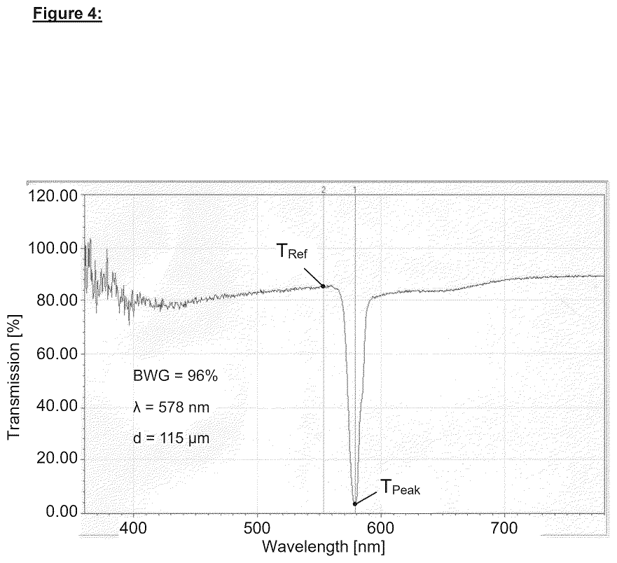

FIG. 4 shows the measurement curve with the corresponding measurement points of sample C.

The table values of the exposures (Tab. 12) show that all samples achieve a high diffraction efficiency of over 80% at a layer thickness of over 100 μm. The exposures of the photopolymerizable compositions B and C according to the invention even achieve a higher value than the comparison mixture A.

The haze values of the UV exposure samples D, E and F were measured with a hazemeter (haze-gard i from BYK) using a 4 mm aperture diaphragm according to the ASTM D 1003 standard procedure. The table values (Tab. 13) show that different turbidities can be achieved by different exposure intensities. With a layer thickness of about 0.9 mm, the difference can be more than 70%. The two measurements of the comparison sample D show that the exposure temperature also has an influence. In contrast to the compositions E and F according to the invention, the liquid comparison mixture D is not clear at 21° C.

### Manufacturing

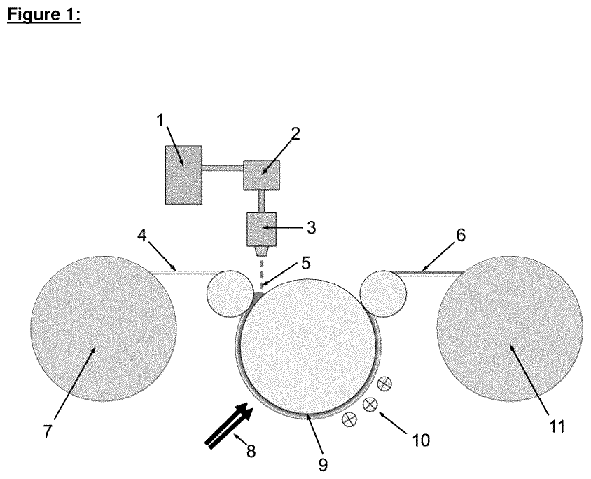

FIG. 1 shows the schematic construction of a compact roll-to-roll machine for the production of holographic contact copies from the claimed photopolymerizable composition.

### REFERENCE SIGNS IN FIG. 1

1 Storage container
2 Filter and degasser
3 Dosing unit
4 Support foil
5 Photopolymer (photopolymerizable composition)
6 Support foil with hologram
7 Foil unwinding
8 Laser light
9 Master
10 UV-light
11 Foil winder

1-15. (canceled)

16. A photopolymerizable composition curable by UV/VIS irradiation comprising:
a) 25% to 74.9% by weight of at least one monomer M comprising at least one ethylenically unsaturated group or of a monomer mixture comprising at least two monomers M comprising different ethylenically unsaturated groups,
b) 25% to 74.9% by weight of an aliphatic urethane acrylate or a mixture of different aliphatic urethane acrylates,
c) 0.1% to 10% by weight of a photoinitiator which activates the polymerization of the monomers and urethane acrylates upon exposure to actinic radiation;
wherein the photopolymerizable composition is liquid at a standard pressure in the range of 15° C. to 150° C. and is suitable as a recording material for optical elements with refractive index modulation,
wherein the photoinitiator contains a dye and as co-initiator a borate salt, and
wherein component a) comprises a bisphenol A diacrylate in an amount of more than 25% by weight, based on the total weight of component a).

17. The photopolymerizable composition according to claim 16,
wherein the difference between the refractive indices of component a) and component b) at 20° C. is at least 0.02.

18. The photopolymerizable composition according to claim 16,
wherein the co-initiator is selected from the group consisting of tetrabutylammonium tetrahexylborate, tetrabutylammonium triphenylhexylborate, tetrabutylammonium tris-(3-fluorophenyl)-hexylborate and tetrabutylammonium tris-(3-chloro-4-methylphenyl)-hexylborate or mixtures thereof.

19. The photopolymerizable composition according to claim 16, wherein the viscosity of the photopolymerizable composition at 20° C. is at least 2000 mPa·s.

20. The photopolymerizable composition according to claim 16, wherein component b) is an aliphatic urethanediacrylate resin or a difunctional aliphatic urethanediacrylate resin.

21. An element comprising a component obtainable by exposure of the photopolymerizable composition according to claim 16 to UV/VIS radiation.

22. The element according to claim 21, comprising a component having transparent and/or translucent regions.

23. The element according to claim 21, comprising a hologram obtainable by exposing the photopolymerizable composition to modulated radiation carrying holographic information.

24. A film, lens, grating, prism, mirror, beam splitter, diffuser, surface relief, optical switch or sensor comprising the element according to claim 21.

25. A head-up display, a laminated glass pane, data glasses, a light guidance system, a spectrometer, a detection system, a security element or a label comprising the element according to claim 21.

26. A process for the preparation of the element according to claim 21 in which the element is subjected to a temperature of more than 100° C. and a pressure of more than 2 bar.

27. A method of forming a light stable hologram in a photopolymerizable layer on a substrate surface or copy master, comprising exposing a layer of the photopolymerizable composition according to claim 16 to modulated radiation carrying holographic information.

28. A process in which the photopolymerizable composition of claim 16 is applied and exposed within one minute.

29. The element according to claim 21, wherein the UV/VIS radiation is actinic UV/VIS radiation.

30. A process for the preparation of the photopolymerizable composition according to claim 16 in which composition is subjected to a temperature of more than 100° C. and a pressure of more than 2 bar.
